(19) United States
(12) Patent Application Publication
(10) Pub. No.: US 2011/0067910 A1
(43) Pub. Date: Mar. 24, 2011

(54) COMPONENT SECURING SYSTEM AND ASSOCIATED METHOD

(75) Inventors: Michael J. Domitrovits, Poughkeepsie, NY (US); Emanuele F. Lopergolo, Poughkeepsie, NY (US); Prabjit Singh, Poughkeepsie, NY (US)

(73) Assignee: International Business Machines Corporation, Armonk, NY (US)

(21) Appl. No.: 12/562,499

(22) Filed: Sep. 18, 2009

(51) Int. Cl. H05K 1/18; H05K 3/30

(52) U.S. Cl. 174/260; 29/832

(57) ABSTRACT

A system to secure a component to a circuit board may include a printed circuit board, a surface mounted component, and a lead carried by the surface mounted component. The system may also include a stencil adhered between at least one of the printed circuit board and the surface mounted component, and the lead adjacent the stencil.

### BACKGROUND OF THE INVENTION

1. Field of the Invention

The invention relates to the field of computer systems, and, more particularly, to data compression in such.

2. Description of Background

A printed circuit board may be a platform for carrying electronic components as well as providing conductive pathways for such. Surface mounted technology (“SMT”) is a method of connecting an electronic component to a printed circuit board. Such a mounted electronic component may be referred to as a surface mounted component.

### SUMMARY OF THE INVENTION

According to one embodiment of the invention, a system to secure a component to a circuit board may include a printed circuit board, a surface mounted component, and a lead carried by the surface mounted component. The system may also include a stencil adhered between at least one of the printed circuit board and the surface mounted component. The system may further include the lead being adjacent to the stencil.

The stencil may surround a portion of the lead. The system may further include a substance conductively joining the printed circuit board and the lead. The substance may comprise solder.

The stencil's coefficient of thermal expansion may be substantially similar to the printed circuit board's coefficient of thermal expansion. The stencil may be nonconductive and/or rigid.

The lead may comprise a plurality of leads in spaced relations. The surface mounted component may comprise a plurality of components assembled in a non-rigid assembly.

The adhesion may be provided by a resin. The resin's coefficient of thermal expansion may be substantially similar to the printed circuit board's and/or the stencil's coefficients of thermal expansion.

Another aspect of the invention is a method to secure a component to a circuit board. The method may include adhering a stencil to a printed circuit board. The method may further include positioning a surface mounted component adjacent the stencil and opposite the printed circuit, and where a lead carried by the surface mounted component is adjacent the printed circuit board and the stencil. The method may additionally include conductively joining the printed circuit board and the lead. The method may also include positioning at least a portion of the lead within the stencil.

In one embodiment, the system may include a printed circuit board, a surface mounted component, a lead carried by the surface mounted component, and a resin. The system may also include a stencil adhered by the resin between the printed circuit board and/or the surface mounted component. The system may further include the stencil being adjacent to the lead. The system may additionally include a substance conductively joining the printed circuit board and the lead.

### BRIEF DESCRIPTION OF THE DRAWINGS

FIG. 1 is a schematic block diagram of a system to secure a component in accordance with the invention.

FIG. 2 is a schematic block diagram side view of FIG. 1.

FIG. 3 is a schematic block diagram of a surface mounted component in accordance with the invention.

FIG. 4 is a schematic block diagram illustrating the placement of the leads carried by the surface mounted component in accordance with the invention.

FIG. 5 is a schematic block diagram illustrating the positioning of the stencil and substance in accordance with the invention.

FIG. 6 illustrates some of the leads surrounded by the stencil in accordance with the invention.

FIG. 7 is a flowchart illustrating method aspects in accordance with the invention.

FIG. 8 is a flowchart illustrating method aspects according to the method of FIG. 7.

### DETAILED DESCRIPTION OF THE INVENTION

Aspects of the invention are described below with reference to flowchart illustrations and/or block diagrams of methods, and apparatus (systems) according to embodiments of the invention. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

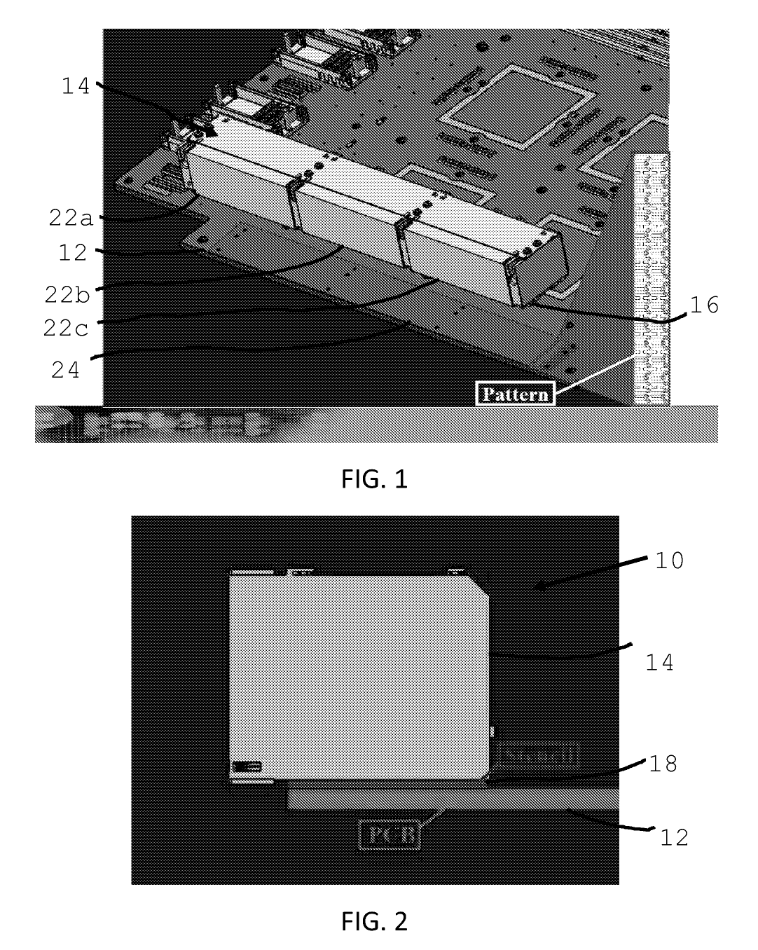

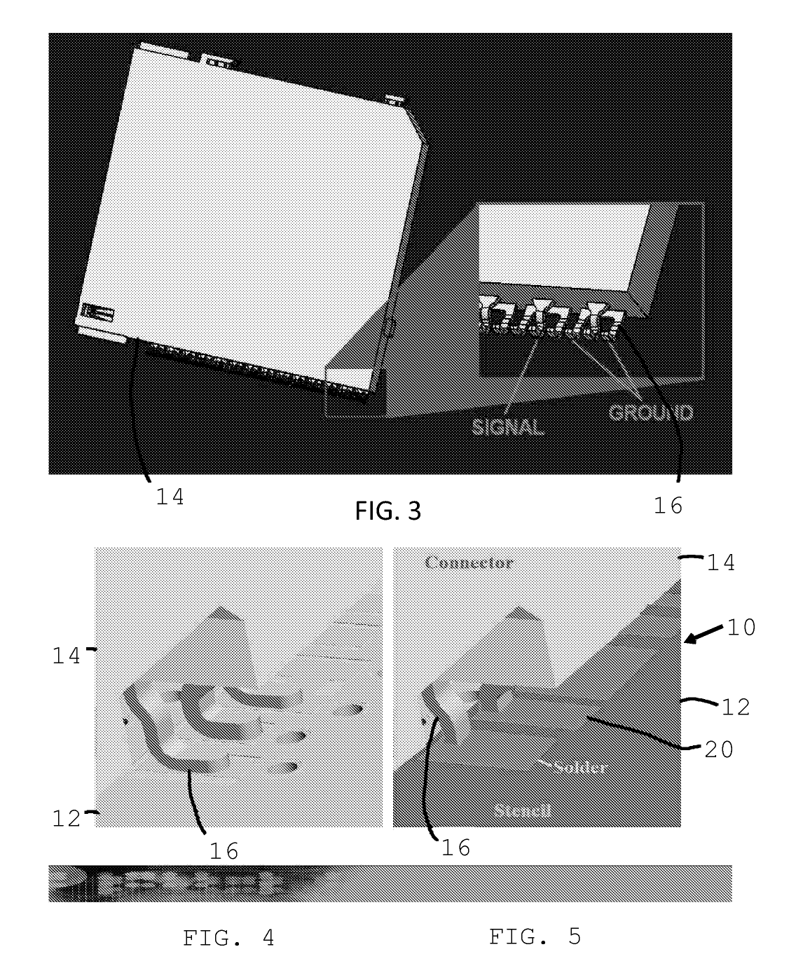

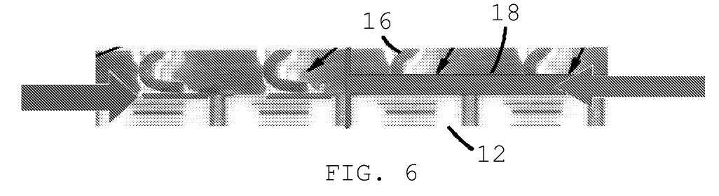

With reference now to FIGS. 1-6, a system 10 to secure a component to a circuit board or the like, is initially described. In one embodiment, the system 10 includes a printed circuit board 12, a surface mounted component 14, and a lead 16 carried by the surface mounted component. In another embodiment, the lead 16 conductively connects the surfaced mounted component 14 and the printed circuit board 12.

In one embodiment, the system 10 includes a stencil 18 adhered between at least one of the printed circuit board 12 and the surface mounted component 14. In one embodiment, the system 10 further includes the lead 16 being adjacent to the stencil 18. In other words, at least one surface of the lead 16 is next to the stencil 18.

In one embodiment, the stencil 18 surrounds a portion of the lead 16. Stated another way, all sides of the portion of the lead 16 are next to the stencil 18. In another embodiment, the system 10 includes a substance 20 conductively joining the printed circuit board 12 and the lead 16. In one embodiment, the substance 20 comprises solder.

In one embodiment, the stencil's 18 coefficient of thermal expansion is substantially similar to the printed circuit board's 12 coefficient of thermal expansion. In another embodiment, the stencil 18 is nonconductive and/or rigid.

In one embodiment, the lead 16 comprises a plurality of leads in spaced relations. In another embodiment, the surface mounted component 14 comprises a plurality of components 22a-22b assembled in an assembly. In one embodiment, the assembly is non-rigid.

In one embodiment, the adhesion is provided by a resin 24. In another embodiment, the resin's 24 coefficient of thermal expansion is substantially similar to the printed circuit board's 12 and/or the stencil's 18 coefficients of thermal expansion.

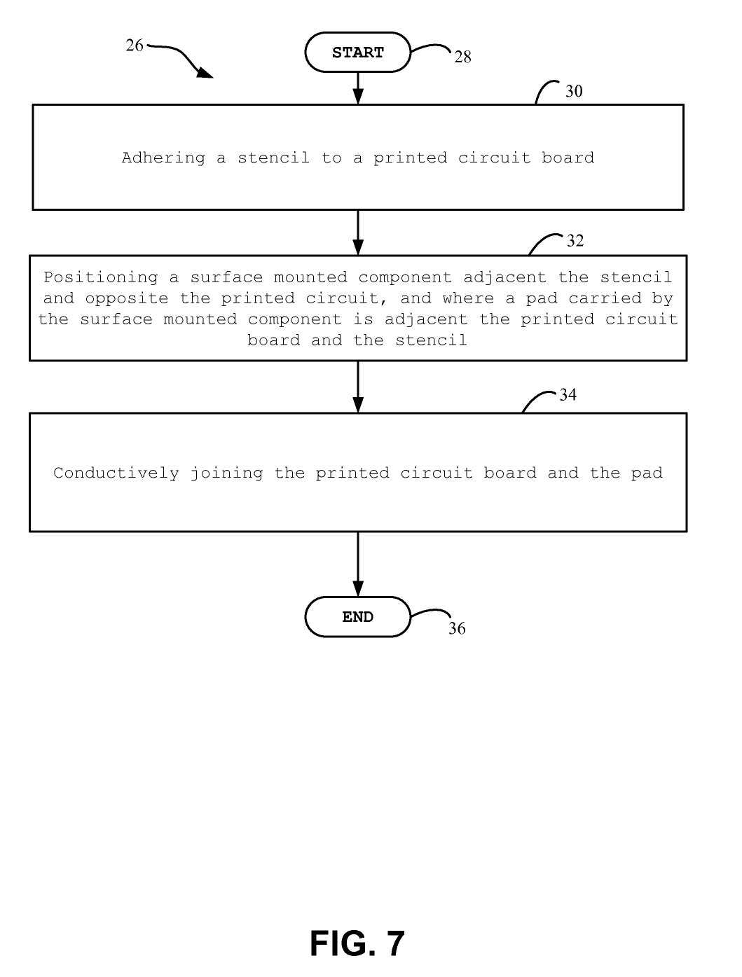

Another aspect of the invention is a method to secure a component to a circuit board, which is now described with reference to flowchart 26 of FIG. 7. The method begins at Block 28 and may include adhering a stencil to a printed circuit board at Block 30. The method may also include positioning a surface mounted component adjacent the stencil and opposite the printed circuit, and where a lead carried by the surface mounted component is adjacent the printed circuit board and the stencil at Block 32. The method may further include conductively joining the printed circuit board and the lead at Block 34. The method ends at Block 36.

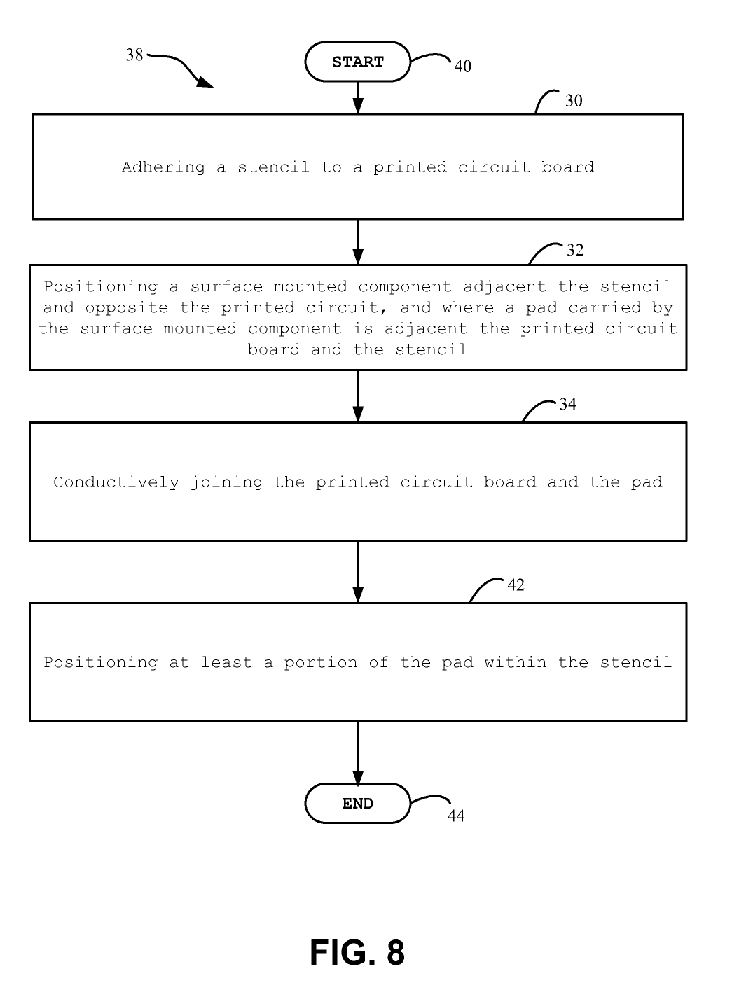

In another method embodiment, which is now described with reference to flowchart 38 of FIG. 8, the method begins at Block 40. The method may include the steps of FIG. 7 at Blocks 30-34. The method may additionally include positioning at least a portion of the lead within the stencil at Block 42. The method ends at Block 44.

In one embodiment, the system 10 includes a printed circuit board 12, a surface mounted component 14, a resin 24, and a lead 16 carried by the surface mounted component. In another embodiment, the system 10 also include a stencil 18 adhered by the resin 24 between the printed circuit board 12 and/or the surface mounted component 14.

In one embodiment, the system 10 further includes the stencil 18 being adjacent to the lead 16. In another embodiment, the system 10 additionally includes a substance 20 conductively joining the printed circuit board 12 and the lead 16.

In view of the foregoing, the system 10, in one embodiment, may secure a component to a circuit board.

For example, surface mount, large area array connectors suffer from the fact that the solder joints have to bear all the mating mechanical loads. By design, solder joints should be expected to carry electrical current, not to provide mechanical strength to the connector structure. Known solutions provide mechanical relief to the connector solder joints by bolting the connector to the printed circuit board. But this solution adds unnecessary hardware to the connector, taking up real estate on the circuit board.

An additional solution is required that does not take up additional real estate on the circuit board, requiring no additional hardware and readily applicable to hardware already built. As a result, the system 10 proposed solution is to adhere a permanently bonded nonconductive stencil to the SMT array to improve axial loading.

For instance, when plugging a daughtercard connector, the surface mount solder joints may absorb the majority of the load, which may cause unacceptable stresses and fractures in the solder joints. In other words, such may result in soldered SMT pads providing most of the support load during plugging.

The system 10 addresses the foregoing problem by adding a stencil 18 bonded to the printed circuit board 12. The stencil 18 reduces shear stress on the solder joints and SMT pads 16, reduces solder shorts, improves rigidity of the printed circuit board 12, improve alignment, reduce pad delamination, and improves electrical shielding, if designed to isolate signals.

In one embodiment, the load is distributed through the stencil 18 to reduce the stress on the SMT pad. In another embodiment, the stencil 18 is thicker than traditional stencils because solder shorts would not be a concern.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A system comprising:
a printed circuit board;
a surface mounted component;
a lead carried by said surface mounted component; and
a stencil adhered between at least one of said printed circuit board and said surface mounted component, and said lead adjacent to said stencil.

2. The system of claim 1 wherein said stencil surrounds a portion of said lead.

3. The system of claim 1 further comprising a substance conductively joining said printed circuit board and said lead.

4. The system of claim 3 wherein said substance comprises solder.

5. The system of claim 1 wherein said stencil's coefficient of thermal expansion is substantially similar to said printed circuit board's coefficient of thermal expansion.

6. The system of claim 1 wherein said stencil is at least one of nonconductive and rigid.

7. The system of claim 1 wherein said lead comprises a plurality of leads in spaced relations.

8. The system of claim 7 wherein said surface mounted component comprises a plurality of components assembled in a non-rigid assembly.

9. The system of claim 1 wherein the adhesion is provided by a resin.

10. The system of claim 9 wherein the resin's coefficient of thermal expansion is substantially similar to said printed circuit board's and said stencil's coefficients of thermal expansion.

11. A method comprising:
adhering a stencil to a printed circuit board;
positioning a surface mounted component adjacent the stencil and opposite the printed circuit, and where a lead carried by the surface mounted component is adjacent to the printed circuit board and the stencil; and
conductively joining the printed circuit board and the lead.

12. The method of claim 11 further comprising positioning a portion of the lead within the stencil.

13. The method of claim 11 wherein adhering the stencil to the printed circuit board includes using a resin having coefficient of thermal expansion substantially similar to said printed circuit board's and said stencil's coefficients of thermal expansion.

14. A system comprising:
a printed circuit board;
a surface mounted component;
a lead carried by said surface mounted component;
a resin;
a stencil adhered by said resin between at least one of said printed circuit board and said surface mounted component, and said stencil adjacent to said lead; and
a substance conductively joining said printed circuit board and said lead.

15. The system of claim 14 wherein said stencil surrounds a portion of said lead.

16. The system of claim 14 wherein said substance comprises solder.

17. The system of claim 14 wherein said stencil is at least one of nonconductive and rigid.

18. The system of claim 14 wherein said lead comprises a plurality of leads in spaced relations.

19. The system of claim 18 wherein said surface mounted component comprises a plurality of components assembled in a non-rigid assembly.

20. The system of claim 14 wherein the resin's coefficient of thermal expansion is substantially similar to said printed circuit board's and said stencil's coefficients of thermal expansion.
